(19) United States
(12) Patent Application Publication
(10) Pub. No.: US 2024/0332216 A1
(43) Pub. Date: Oct. 3, 2024

(54) MOLDED COMPOUND PATTERNS ON PACKAGE BALL SIDE TO MITIGATE COPLANARITY AND WARPAGE

(71) Applicant: Micron Technology, Inc., Boise, ID (US)

(72) Inventors: See Hiong LEOW, Singapore (SG); Hong Wan NG, Singapore (SG); Kelvin Aik Boo TAN, Singapore (SG); Seng Kim YE, Singapore (SG); Ling PAN, Singapore (SG); Chin Hui CHONG, Singapore (SG)

(21) Appl. No.: 18/606,208

(22) Filed: Mar. 15, 2024

Related U.S. Application Data
(60) Provisional application No. 63/492,671, filed on Mar. 28, 2023.

(51) Int. Cl. H01L 23/00; H01L 21/48; H01L 23/31; H01L 23/498; H01L 25/065; H01L 25/18; H10B 80/00

(52) U.S. Cl. CPC H01L 23/564; H01L 21/4853; H01L 23/49816; H01L 23/3128; H01L 25/0652; H01L 25/18; H10B 80/00

(57) ABSTRACT

Implementations described herein relate to various semiconductor device assemblies. In some implementations, a semiconductor device assembly includes a circuit substrate comprising a first substrate surface and a second substrate surface arranged opposite to the first substrate surface; at least one die arranged on the first substrate surface; a package casing disposed over the first substrate surface, wherein the package casing encapsulates the at least one die and covers at least part of the first substrate surface; a plurality of conductive interconnect structures coupled to the second substrate surface, wherein the plurality of conductive interconnect structures are electrically coupled to the at least one die via the circuit substrate; and at least one molded compound structure arranged on the second substrate surface, wherein the at least one molded compound structure is configured to reduce a coplanarity of the plurality of conductive interconnect structures.

### CROSS REFERENCE TO RELATED APPLICATION

This patent application claims priority to U.S. Provisional Patent Application No. 63/492,671, filed on Mar. 28, 2023, and entitled “MOLDED COMPOUND PATTERNS ON PACKAGE BALL SIDE TO MITIGATE COPLANARITY AND WARPAGE.” The disclosure of the prior application is considered part of and is incorporated by reference into this patent application.

### TECHNICAL FIELD

The present disclosure generally relates to semiconductor devices and methods of forming semiconductor devices. For example, the present disclosure relates to molded compound patterns arranged on a package ball side to mitigate coplanarity and warpage.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2A is a diagram of a ball side of a semiconductor package assembly according to one or more implementations.

FIG. 2B is a diagram of a ball side of a semiconductor package assembly according to one or more implementations.

FIG. 2C is a diagram of a ball side of a semiconductor package assembly according to one or more implementations.

FIG. 3 is a flowchart of an example method of forming a semiconductor package assembly.

FIG. 4 shows a diagram that illustrates a coplanarity of a semiconductor package assembly.

### DETAILED DESCRIPTION

A semiconductor package assembly may be one type of semiconductor device assembly that is structured to house one or more dies. Typically, one or more dies are attached to a die side of a circuit substrate, and a package casing, such as a molded compound casing, is disposed over the die side of the circuit substrate to encapsulate the one or more dies. Conductive interconnect structures, such as solder balls, may be attached to a back-side of the circuit substrate to provide electrical connections to the one or more dies.

Coplanarity of electronic components such as surface mounted devices and connectors is defined as a maximum value of a difference between a highest point and lowest point among multiple conductive interconnect structures. Such conductive interconnect structures may include contact pins of pin grid arrays (PGAs), solder balls of ball grid arrays (BGAs), or connector pins. The larger the difference between the highest point and the lowest point among the multiple conductive interconnect structures, the larger the coplanarity is for the multiple conductive interconnect structures. Meanwhile, a smaller difference between the highest point and the lowest point among the multiple conductive interconnect structures, the smaller the coplanarity is for the multiple conductive interconnect structures. An increase in coplanarity can lead to a gap between one or more conductive interconnect structures and the circuit substrate. Any gap that exceeds an allowable range (e.g., tolerance) can cause problems, such as connection failures of electronic devices mounted on boards, contact failures of connectors, or connection failures caused by even a slight load during use. Therefore, mitigating coplanarity can reduce or prevent connection and contact failures from occurring.

The package casing formed on the die side of a circuit substrate may cause the coplanarity to increase. For example, as the package casing may shrink at lower temperatures and expand at higher temperatures. The package casing and the circuit substrate may have different coefficients of thermal expansion (e.g., a mismatch in coefficients of thermal expansion). As a result, of the mismatch in coefficients of thermal expansion the package casing and the circuit substrate may shrink or expand by different amounts. As the package casing shrinks by a different amount compared to a shrinking of the circuit substrate, the package casing may induce a mechanical stress in the circuit substrate. The mechanical stress may cause the circuit substrate to bend or warp. For example, as the package casing shrinks, a ratio between the circuit substrate and the package casing may become unbalanced (e.g., due to a mismatch in coefficients of thermal expansion of the circuit substrate and the package casing). The ratio imbalance may cause a coplanarity of the conductive interconnect structures to increase due to warpage of the circuit substrate caused by the change in ratio. The induced mechanical stress may be more prevalent at certain temperatures due to the mismatch in the coefficients of thermal expansion. In addition, the circuit substrate may be printed with a soldermask material on the die side and the back side. A variation in the soldermask and copper thickness of the circuit substrate may also contribute to an increase in the coplanarity of the conductive interconnect structures.

In some cases, the warpage of the circuit substrate may occur at or near the edges of the circuit substrate in a peripheral region of the back-side of the circuit substrate, causing the contact points of some of the conductive interconnect structures closest to the peripheral region to shift relative to conductive interconnect structures located further away from the peripheral region. This shift may cause the coplanarity of the conductive interconnect structures to increase.

In some implementations, a molded compound pattern that includes one or more molded compound structures may be formed on the back side of the circuit substrate (e.g., on the solder ball side of the circuit substrate), opposite to the package casing, to counterbalance the mismatch in the coefficients of thermal expansion between the circuit substrate and the package casing. In other words, the at least one molded compound structure is configured to reduce a coplanarity of the plurality of conductive interconnect structures that is arranged on the back side of the circuit substrate. The at least one molded compound structure may be used to counterbalance a mechanical stress induced in the circuit substrate by the package casing, thereby reducing warpage of the circuit substrate and mitigating the coplanarity of the plurality of conductive interconnect structures. Depending on a warpage profile of the circuit substrate, the molded compound pattern can be tailored to include one or more molded strip structures, one or more molded ring structures, and/or one or more molded button or block structures to counterbalance the warpage profile and reduce the warpage.

In some implementations, the at least one molded compound structure is arranged in a peripheral region or edge region of the back side of the circuit substrate, where the peripheral region or edge region surround an area of the back side in which the plurality of conductive interconnect structures are arranged. Thus, the at least one molded compound structure can be arranged in a location where warpage may be most prevalent. The molded compound pattern may provide increased flexibility in controlling the warpage profile with a broader choice of molding compound properties. In addition, the molded compound pattern may enable a tightened, smaller package footprint by minimizing warpage caused by the package casing and other influences.

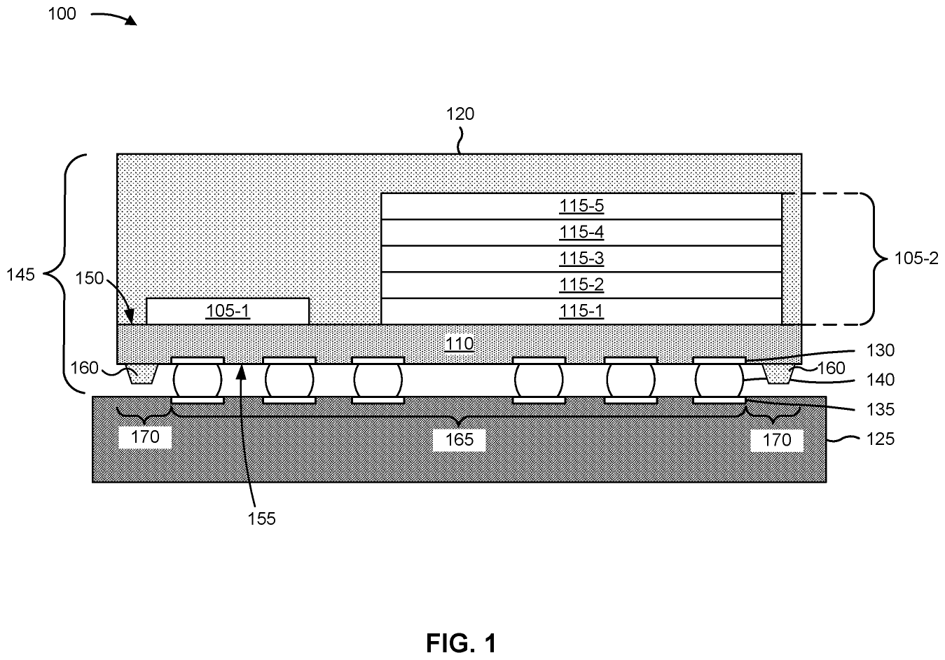

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110 (e.g., a circuit substrate, a substrate interposer, or a conductive interconnect substrate). An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher-level system (e.g., a computer, a mobile phone, a network device, an SSD, a vehicle, or an Internet of Things device), such as by electrically connecting the apparatus 100 to a circuit board 125, such as a printed circuit board (PCB). For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The substrate 110 may include interconnections that electrically couple the integrated circuits 105 to the solder balls 140. The interconnections between an integrated circuit 105, the substrate 110, and the circuit board 125 enable the integrated circuit 105 to receive and transmit signals to other components of the apparatus 100 and/or the higher-level system.

The substrate 110, the integrated circuits 105, the casing 120, and the electrical contacts 130, and the solder balls 140 may form a semiconductor package assembly 145 that is coupled to the circuit board 125. A surface of the substrate 110 on which the integrate circuits 105 are disposed may be referred to as a first substrate surface 150 (e.g., arranged at a die side or a front side of the substrate 110). A surface of the substrate 110 to which the solder balls 140 are attached may be referred to as a second substrate surface 155 (e.g., arranged at a ball side or a back side of the substrate 110). Thus, the casing 120 may be disposed over the first substrate surface 150 in order to encapsulate the integrated circuits 105 and cover at least part of the first substrate surface 150.

As the casing 120 shrinks or expands relative to the substrate 110, the casing 120 may induce a mechanical stress in the substrate 110 that may cause the substrate 110 to bend or warp. As a result of the mechanical stress and the warpage occurrent from the mechanical stress, a coplanarity of the solder balls 140 may increase. To counterbalance the mechanical stress and the warpage, one or more molded compound structures 160 may be arranged on (e.g., coupled to) the second substrate surface 155 of the substrate 110 (e.g., on the ball side of the substrate 110). As a result, the one or more molded compound structures 160 may be configured to reduce the warpage of the substrate 110 and reduce a coplanarity of the solder balls 140.

In some implementations, the one or more molded compound structures 160 may be arranged in a molded compound pattern that is configured to mitigate the coplanarity of the plurality of conductive interconnect structures. For example, the molded compound pattern may be configured (e.g., designed or structured) according to a warpage profile of the substrate 110 caused by the casing 120 (e.g., due to a mismatch in coefficients of thermal expansion between the substrate 110 and the casing 120).

The solder balls 140 may be arranged in a ball grid area 165 of the second substrate surface 155 that is surrounded by a peripheral region 170 (e.g., an edge region) of the second substrate surface 155. The one or more molded compound structures 160 may be arranged in the peripheral region 170 of the second substrate surface 155. In some implementations, the one or more molded compound structures 160 are confined to the peripheral region 170 of the second substrate surface 155 such that the ball grid area 165 is devoid of molded compound (e.g., of molded compound structures). By arranging the one or more molded compound structures 160 in the peripheral region 170 of the second substrate surface 155, the one or more molded compound structures 160 can be placed in an area of the second substrate surface 155 where warpage is most prevalent. In other words, the one or more molded compound structures 160, arranged in the peripheral region 170, may be placed in an area where the one or more molded compound structures 160 can be most effective at counterbalancing the mismatch in coefficients of thermal expansion between the substrate 110 and the casing 120 and balancing a shrinking effect of the overall package. Thus, the one or more molded compound structures 160 may counterbalance the warpage of the substrate 110 occurrent from the mismatch in coefficients of thermal expansion between the substrate 110 and the casing 120 by inducing, for example, a mechanical stress in the substrate 110 that is counter to the mechanical stress induced by the casing 120.

The one or more molded compound structures 160 increase a mold volume that is in contact with the substrate 110 and may reduce a shrinking effect of the substrate 110 in lower temperatures. As a result, the coplanarity of the solder balls 140 may be improved (e.g., reduced).

Depending on a warpage profile of the substrate 110, the molded compound pattern can be tailored to include one or more molded strip structures, one or more molded ring structures, and/or one or more molded button or block structures to counterbalance the warpage profile and reduce the warpage.

As indicated above, FIG. 1 is provided as an example. Other examples may differ from what is described with regard to FIG. 1. The number and arrangement of components shown in FIG. 1 are provided as an example. In practice, there may be additional components, fewer components, different components, or differently arranged components than those shown in FIG. 1.

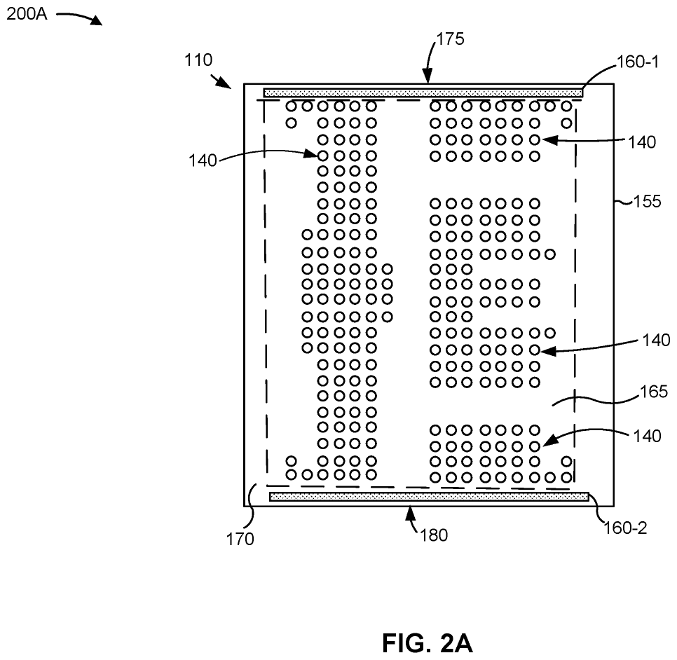

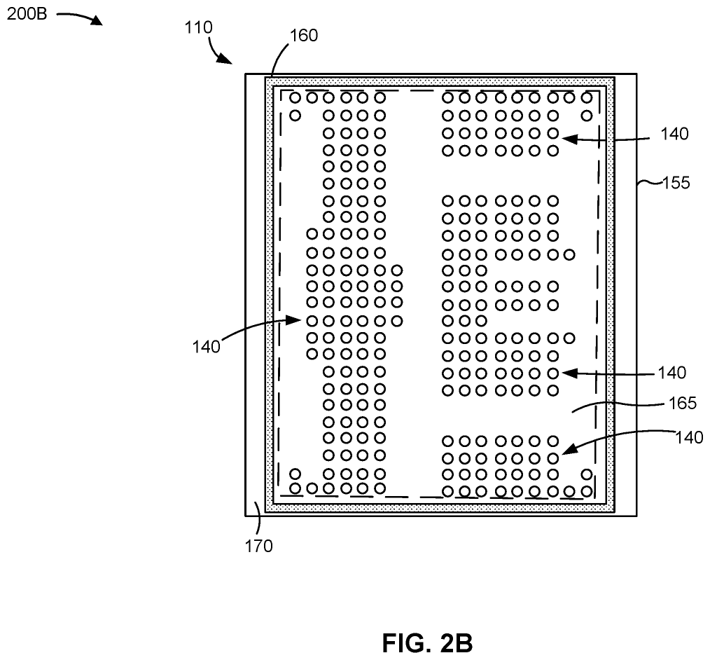

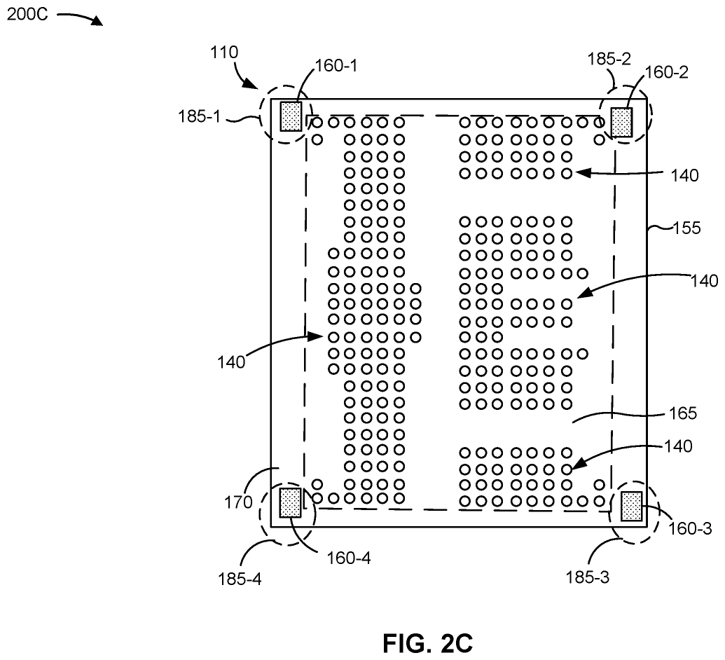

FIG. 2A is a diagram 200A of a ball side of a semiconductor package assembly according to one or more implementations. The semiconductor package assembly may be similar to semiconductor package assembly 145 described above in connection with FIG. 1. Thus, the second substrate surface 155 of the substrate 110 is illustrated in the diagram 200A. The semiconductor package assembly includes the solder balls 140 (e.g., a plurality of conductive interconnect structures) arranged in one or more ball grid arrays in the ball grid area 165 of the second substrate surface 155. The ball grid area 165 may be surrounded by the peripheral region 170. A molded compound pattern may be formed on the second substrate surface 155 in the peripheral region 170 in order to reduce the coplanarity of the solder balls 140, as described in connection with FIG. 1.

The molded compound pattern may include a plurality of molded compound structures 160, including a first molded compound structure 160-1 and a second molded compound structure 160-2, arranged in the peripheral region 170 of the second substrate surface 155. The first molded compound structure 160-1 may be a molded strip structure (e.g., having a strip shape) arranged in the peripheral region 170 proximate to a first edge 175 of the second substrate surface 155. A length dimension of the first molded compound structure 160-1 may extend parallel to the first edge 175. For example, in some implementations, the first molded compound structure 160-1 may extend from one side of the peripheral region 170 to an opposite side of the peripheral region 170 along the first edge 175.

The second molded compound structure 160-2 may be a molded strip structure (e.g., having a strip shape) arranged in the peripheral region 170 proximate to a second edge 180 of the second substrate surface 155. A length dimension of the second molded compound structure 160-2 may extend parallel to the second edge 180. For example, in some implementations, the second molded compound structure 160-2 may extend from one side of the peripheral region 170 to an opposite side of the peripheral region 170 along the second edge 180. In this example, the first molded compound structure 160-1 and the second molded compound structure 160-2 are arranged along opposite edges (e.g., the first edge 175 and the second edge 180). However, in some implementations, the first molded compound structure 160-1 and the second molded compound structure 160-2 may be arranged along perpendicular edges. In addition, in some implementations, three or more molded compound structures 160 may be provided, with each of the molded compound structures 160 being a molded strip structure that extends along a respective edge of the second substrate surface 155. In some implementations, the plurality of molded compound structures 160 may be comprised of multiple discrete segments instead of unitary structures, or two or more molded compound structures 160 may be arranged along a respective edge of the second substrate surface.

As indicated above, FIG. 2A is provided as an example. Other examples may differ from what is described with regard to FIG. 2A.

FIG. 2B is a diagram 200B of a ball side of a semiconductor package assembly according to one or more implementations. The semiconductor package assembly may be similar to semiconductor package assembly 145 described above in connection with FIG. 1. Thus, the second substrate surface 155 of the substrate 110 is illustrated in the diagram 200A. The semiconductor package assembly includes the solder balls 140 (e.g., a plurality of conductive interconnect structures) arranged in one or more ball grid arrays in the ball grid area 165 of the second substrate surface 155. The ball grid area 165 may be surrounded by the peripheral region 170. A molded compound pattern may be formed on the second substrate surface 155 in the peripheral region 170 in order to reduce the coplanarity of the solder balls 140, as described in connection with FIG. 1.

The molded compound pattern may include a molded compound structure 160 that is formed as a ring that surrounds the ball grid area 165. Thus, the molded compound structure 160 encircles the solder balls 140. The molded compound structure 160 may be formed as a single unitary ring structure. In some implementations, the molded compound structure 160 may be formed by multiple discrete segments that encircle the ball grid area 165.

In some implementations, two or more molded ring structures 160 may be formed in the peripheral region 170. For example, the two or more concentric molded ring structures 160 may be formed in the peripheral region 170.

As indicated above, FIG. 2B is provided as an example. Other examples may differ from what is described with regard to FIG. 2B.

FIG. 2C is a diagram 200C of a ball side of a semiconductor package assembly according to one or more implementations. The semiconductor package assembly may be similar to semiconductor package assembly 145 described above in connection with FIG. 1. Thus, the second substrate surface 155 of the substrate 110 is illustrated in the diagram 200A. The semiconductor package assembly includes the solder balls 140 (e.g., a plurality of conductive interconnect structures) arranged in one or more ball grid arrays in the ball grid area 165 of the second substrate surface 155. The ball grid area 165 may be surrounded by the peripheral region 170. A molded compound pattern may be formed on the second substrate surface 155 in the peripheral region 170 in order to reduce the coplanarity of the solder balls 140, as described in connection with FIG. 1.

The molded compound pattern may include a plurality of molded compound structures 160, including a first molded compound structure 160-1, a second molded compound structure 160-2, a third molded compound structure 160-3, and a fourth molded compound structure 160-4, arranged in the peripheral region 170 of the second substrate surface 155. Each of the plurality of molded compound structures 160 may be arranged in a respective corner region 185 of the second substrate surface 155 (e.g., corner regions 185-1, 185-2, 185-3, and 185-4). Additionally, each of the plurality of molded compound structures 160 may be a button structure having, for example, a rectangular or a circular shape. Thus, the each of the plurality of molded compound structures 160 may be formed as a block of molding material.

As indicated above, FIG. 2C is provided as an example. Other examples may differ from what is described with regard to FIG. 2C. In addition, one or more aspects of FIGS. 2A-2C may be combined. For example, one or more aspects of the molded compound pattern described in FIG. 2A may be combined with one or more aspects of the molded compound pattern described in FIG. 2B and/or FIG. 2C, or one or more aspects of the molded compound pattern described in FIG. 2B may be combined with one or more aspects of the molded compound pattern described in FIG. 2A and/or FIG. 2C, or one or more aspects of the molded compound pattern described in FIG. 2C may be combined with one or more aspects of the molded compound pattern described in FIG. 2A and/or FIG. 2B.

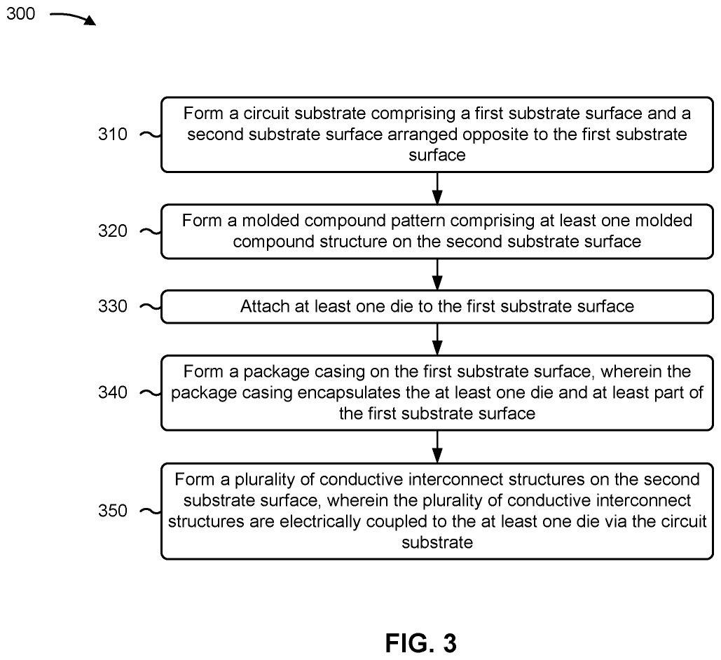

FIG. 3 is a flowchart of an example method 300 of forming a semiconductor package assembly. In some implementations, one or more process blocks of FIG. 3 may be performed by various semiconductor manufacturing equipment.

As shown in FIG. 3, the method 300 may include forming a circuit substrate comprising a first substrate surface and a second substrate surface arranged opposite to the first substrate surface (block 310). The circuit substrate may be a PCB and may have a soldermask formed on the first substrate surface and/or the second substrate surface. The circuit substrate may be an assembly strip having a plurality of device regions, where each device region corresponds to a different semiconductor package assembly.

As further shown in FIG. 3, the method 300 may include forming a molded compound pattern comprising at least one molded compound structure on the second substrate surface (block 320). Since solder balls may eventually formed on the second substrate surface, the second substrate surface may be referred to as the ball side of the semiconductor package assembly. In some implementations, a compression molding process may be used to form the at least one molded compound structure on the second substrate surface. The molded compound pattern may be formed in one or more selective localized molding areas on the second substrate surface to balance a shrinking effect of the overall package of the semiconductor package assembly (e.g., at low temperatures). For example, the molded compound pattern may be confined to a peripheral region of the second substrate surface.

As further shown in FIG. 3, the method 300 may include attaching at least one die to the first substrate surface (block 330). In some implementations, attaching the at least one die to the first substrate surface may be performed subsequent to forming the molded compound pattern in block 320.

As further shown in FIG. 3, the method 300 may include forming a package casing on the first substrate surface, wherein the package casing encapsulates the at least one die and at least part of the first substrate surface (block 340). For example, a compression molding process may be used to form the package casing on the first substrate surface. In addition, additional intermediate processes may be performed between block 330 and block 340. For example, a pre-wire bond process, a wire bonding process, and a post-wire bond process may be performed between block 330 and block 340.

As further shown in FIG. 3, the method 300 may include forming a plurality of conductive interconnect structures on the second substrate surface, wherein the plurality of conductive interconnect structures are electrically coupled to the at least one die via the circuit substrate (block 350). In some implementations, the conductive interconnect structures may be solder balls. In some implementations, forming the plurality of conductive interconnect structures on the second substrate surface may be performed subsequent to forming the molded compound pattern in block 320. In some implementations, forming the plurality of conductive interconnect structures on the second substrate surface may be performed subsequent to forming the molded compound pattern in block 320 and subsequent to forming the package casing on the first substrate surface in block 340. The at least one molded compound structure of the molded compound pattern is configured to reduce a coplanarity of the plurality of conductive interconnect structures. The plurality of conductive interconnect structures may be surrounded by the peripheral region of the second substrate surface in which the molded compound pattern is formed.

Following the formation of the conductive interconnect structures, multiple semiconductor package assemblies formed on the circuit substrate (e.g., the assembly strip) may be singulated into separate semiconductor package assemblies. Each semiconductor package assembly may have a corresponding molded compound pattern arranged in a peripheral region that surrounds the conductive interconnect structures of that semiconductor package assembly.

The method 300 may include additional aspects, such as any single aspect or any combination of aspects described below and/or in connection with one or more other methods described elsewhere herein.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the semiconductor package assembly 145, an integrated assembly that includes the semiconductor package assembly 145, any part described herein of the semiconductor package assembly 145, and/or any part described herein of an integrated assembly that includes the semiconductor package assembly 145. For example, the method 400 may include forming one or more of the parts 105, 110, 120, 130, 140, and/or 160.

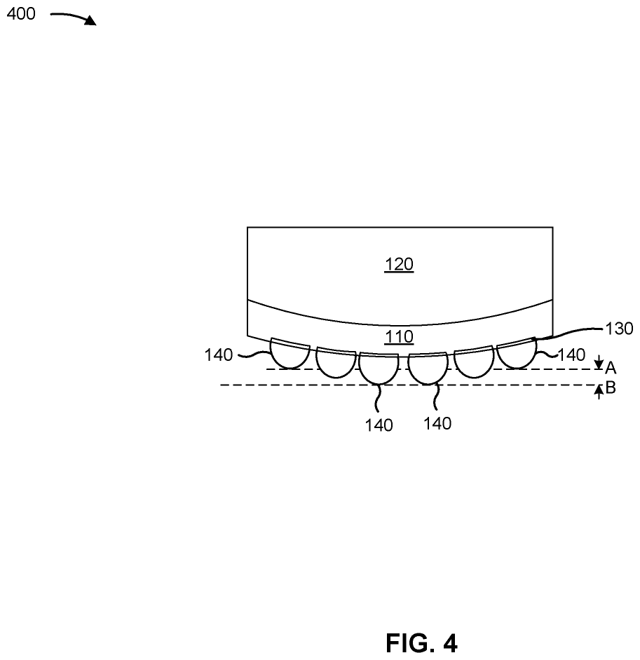

FIG. 4 shows a diagram 400 that illustrates a coplanarity of a semiconductor package assembly. The semiconductor package assembly may include substrate 110, casing 120, electrical contacts 130, and solder balls 140. A warpage of the substrate 110 is exaggerated to demonstrate a coplanarity that introduces a gap between a highest point, denoted by line A, and a lowest point, denoted by line B, among the solder balls 140. As described above, coplanarity is defined as a maximum value of a difference between a highest point and lowest point among multiple conductive interconnect structures, such as the solder balls 140. The larger the difference between lines A and B, the larger the coplanarity is for the solder balls 140. Meanwhile, the smaller the difference between lines A and B, the smaller the coplanarity is for the solder balls 140. By attaching a molded compound pattern (not shown) to the ball side of the substrate 110 in the manner described above, the warpage of the substrate 110 may be reduced. As a result, the coplanarity of the solder balls 140 can be reduced such that the difference between lines A and B is reduced. Mitigating the coplanarity of the solder balls 140 can reduce or prevent connection and contact failures from occurring.

As indicated above, FIG. 4 is provided as an example. Other examples may differ from what is described with regard to FIG. 4. For example, the warpage of the substrate 110 can occur in a variety of ways and may have a different profile than the warpage shown in FIG. 4.

In some implementations, a semiconductor device assembly includes a circuit substrate comprising a first substrate surface and a second substrate surface arranged opposite to the first substrate surface; at least one die arranged on the first substrate surface; a package casing disposed over the first substrate surface, wherein the package casing encapsulates the at least one die and covers at least part of the first substrate surface; a plurality of conductive interconnect structures coupled to the second substrate surface, wherein the plurality of conductive interconnect structures are electrically coupled to the at least one die via the circuit substrate; and at least one molded compound structure arranged on the second substrate surface, wherein the at least one molded compound structure is configured to reduce a coplanarity of the plurality of conductive interconnect structures.

In some implementations, a semiconductor device assembly includes a substrate comprising a first substrate surface and a second substrate surface arranged opposite to the first substrate surface; a die coupled to the first substrate surface of the substrate; a molded casing disposed on the first substrate surface of the substrate, wherein the molded housing encapsulates the die and covers at least part of the first substrate surface; a ball grid array coupled to the second substrate surface, wherein the ball grid array is electrically coupled to the die via the substrate; and at least one molded compound structure coupled to the second substrate surface, wherein the at least one molded compound structure is arranged in an edge region of the second substrate surface that surrounds the ball grid array, and wherein the at least one molded compound structure is configured to reduce a coplanarity of the ball grid array.

In some implementations, a method of manufacturing a semiconductor device assembly includes forming a circuit substrate comprising a first substrate surface and a second substrate surface arranged opposite to the first substrate surface; forming a molded compound pattern comprising at least one molded compound structure on the second substrate surface; subsequent to forming the molded compound pattern, attaching at least one die to the first substrate surface; forming a package casing on the first substrate surface, wherein the package casing encapsulates the at least one die and at least part of the first substrate surface; and forming a plurality of conductive interconnect structures on the second substrate surface, wherein the plurality of conductive interconnect structures are electrically coupled to the at least one die via the circuit substrate, and wherein the at least one molded compound structure is configured to reduce a coplanarity of the plurality of conductive interconnect structures.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate comprising a first substrate surface and a second substrate surface arranged opposite to the first substrate surface;
at least one die arranged on the first substrate surface;
a package casing disposed over the first substrate surface, wherein the package casing encapsulates the at least one die and covers at least part of the first substrate surface;
a plurality of conductive interconnect structures coupled to the second substrate surface, wherein the plurality of conductive interconnect structures are electrically coupled to the at least one die via the circuit substrate; and
at least one molded compound structure arranged on the second substrate surface, wherein the at least one molded compound structure is configured to reduce a coplanarity of the plurality of conductive interconnect structures.

2. The semiconductor device assembly of claim 1, wherein the at least one molded compound structure is configured to reduce a warpage of the circuit substrate.

3. The semiconductor device assembly of claim 1, wherein the at least one molded compound structure is arranged in a molded compound pattern that is configured to mitigate the coplanarity of the plurality of conductive interconnect structures.

4. The semiconductor device assembly of claim 1, wherein the at least one molded compound structure is configured to counterbalance a mechanical stress induced onto the circuit substrate by the package casing.

5. The semiconductor device assembly of claim 1, wherein the at least one molded compound structure is arranged in a peripheral region of the second substrate surface, and
wherein the plurality of conductive interconnect structures is surrounded by the peripheral region of the second substrate surface.

6. The semiconductor device assembly of claim 5, wherein the plurality of conductive interconnect structures are solder balls are arranged in a ball grid area of the second substrate surface that is surrounded by the peripheral region of the second substrate surface.

7. The semiconductor device assembly of claim 5, wherein the at least one molded compound structure includes a molded ring structure arranged in the peripheral region of the second substrate surface, wherein the molded ring structure surrounds the plurality of conductive interconnect structures.

8. The semiconductor device assembly of claim 5, wherein the at least one molded compound structure includes a first molded strip structure arranged in the peripheral region of the second substrate surface, proximate to a first edge of the second substrate surface, wherein a length dimension of the first molded strip structure extends parallel to the first edge, and
wherein the at least one molded compound structure includes a second molded strip structure arranged in the peripheral region of the second substrate surface, proximate to a second edge of the second substrate surface, wherein a length dimension of the second molded strip structure extends parallel to the second edge.

9. The semiconductor device assembly of claim 8, wherein the first edge is arranged opposite to the second edge.

10. The semiconductor device assembly of claim 5, wherein the at least one molded compound structure includes a plurality of molded compound structures arranged in the peripheral region of the second substrate surface.

11. The semiconductor device assembly of claim 10, wherein the plurality of molded compound structures are arranged in corner regions of the second substrate surface.

12. The semiconductor device assembly of claim 11, wherein each molded compound structure of the plurality of molded compound structures is arranged in a different corner region of the second substrate surface.

13. The semiconductor device assembly of claim 11, wherein the plurality of molded compound structures are button structures, and
wherein the at least one molded compound structure includes a plurality of molded strip structures arranged in the peripheral region of the second substrate surface, wherein each molded strip structure of the plurality of molded strip structures extends along a respective edge of the second substrate surface.

14. A semiconductor device assembly, comprising:
a substrate comprising a first substrate surface and a second substrate surface arranged opposite to the first substrate surface;
a die coupled to the first substrate surface of the substrate;
a molded casing disposed on the first substrate surface of the substrate, wherein the molded housing encapsulates the die and covers at least part of the first substrate surface;
a ball grid array coupled to the second substrate surface, wherein the ball grid array is electrically coupled to the die via the substrate; and
at least one molded compound structure coupled to the second substrate surface,
wherein the at least one molded compound structure is arranged in an edge region of the second substrate surface that surrounds the ball grid array, and
wherein the at least one molded compound structure is configured to reduce a coplanarity of the ball grid array.

15. The semiconductor device assembly of claim 14, wherein the ball grid array is formed in a ball grid area of the second substrate surface that is devoid of molded compound, and
wherein the edge region surrounds the ball grid area.

16. The semiconductor device assembly of claim 14, wherein the at least one molded compound structure forms a ring structure that surrounds the ball grid array, or
wherein the at least one molded compound structure comprises a plurality of discrete molded compound structures.

17. A method of manufacturing a semiconductor device assembly, the method comprising:
forming a circuit substrate comprising a first substrate surface and a second substrate surface arranged opposite to the first substrate surface;
forming a molded compound pattern comprising at least one molded compound structure on the second substrate surface;
subsequent to forming the molded compound pattern, attaching at least one die to the first substrate surface;
forming a package casing on the first substrate surface, wherein the package casing encapsulates the at least one die and at least part of the first substrate surface; and
forming a plurality of conductive interconnect structures on the second substrate surface, wherein the plurality of conductive interconnect structures are electrically coupled to the at least one die via the circuit substrate, and
wherein the at least one molded compound structure is configured to reduce a coplanarity of the plurality of conductive interconnect structures.

18. The method of claim 17, wherein forming the package casing and forming the plurality of conductive interconnect structures are performed after forming the molded compound pattern.

19. The method of claim 17, wherein the molded compound pattern is confined to a peripheral region of the second substrate surface.

20. The method of claim 19, wherein the plurality of conductive interconnect structures are surrounded by the peripheral region of the second substrate surface.
